(19) United States
(12) Patent Application Publication
(10) Pub. No.: US 2006/0278974 A1
(43) Pub. Date: Dec. 14, 2006

(54) Method for forming wafer-level heat spreader structure and package structure thereof

(75) Inventors: Wei-Min Hsiao, Kaohsiung City (TW); Kuo-Pin Yang, Meinong Town (TW)

Correspondence Address: BIRCH STEWART KOLASCH & BIRCH, PO BOX 747, FALLS CHURCH, VA, 22040-0747, US

(73) Assignee: Advanced Semiconductor Engineering. Inc.

(21) Appl. No.: 11/313,858

(22) Filed: Dec. 22, 2005

(30) Foreign Application Priority Data
Jun. 9, 2005 (TW) 94119073

(51) Int. Cl. H01L 23/34

(52) U.S. Cl. 257/706

(57) ABSTRACT

A method for forming wafer-level heat sink in a chip of the packaging structure is provided. Before the sawing process, a plurality of via holes are formed and covered with a heat conductive layer such as a metal layer for forming a heat spreader structure in the backside of a wafer. Hence, each sawn chip that provided with a wafer-level heat sink structure will be able to stack with another chips or boards to form a chip stacking or chip packaging structure.

### RELATED APPLICATIONS

The present application is based on, and claims priority from, Taiwan Application Serial Number 94119073, filed Jun. 9, 2005, the disclosure of which is hereby incorporated by reference herein in its entirety.

### FIELD OF THE INVENTION

The present invention relates to a heat dissipating method and structure for a chip package and structure, and more particularly, to a method for forming a wafer-level heat spreader structure and a package structure fabricated by the method.

### BACKGROUND OF THE INVENTION

As circuit integration continues to increase in an IC chip, the question of how to efficiently dissipate heat generated by the IC chip in operation becomes an important issue in IC chip packaging process. Therefore, it is desirable to find a way to design a chip that has a better heat-dissipating capability without providing any additional heat sink thereon, thereby saving packaging cost and reducing the total thickness of the resulting package.

### SUMMARY OF THE INVENTION

In view of the background of the invention, an additional heat sink is required for a chip in a conventional package to achieve a better heat-dissipating effect. However, this inevitably causes the problems of increasing the packaging cost and the total thickness of the resulting package. Therefore, one objective of the present invention is to provide a method for forming a wafer-level heat spreader structure and the application thereof in order to improve the structure of the chip itself such that the improved chip obtains a better heat-dissipating capability without providing any additional heat sink thereon.

To achieve the above listed and other objects, the present invention provides a method for forming a wafer-level heat spreader structure and a chip package structure manufactured by the method. Before the wafer is diced, a plurality of via holes are formed on the backside surface of the wafer by dry etching and a metal layer is formed over the entire backside surface of the wafer and the surface of the via holes to form a heat spreader structure on the wafer itself. After the wafer is diced into individual chips, each chip is provided with a wafer-level heat spreader structure which is capable of stacking with other chips or carriers to form a chip stack or chip package structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1D illustrate in cross-section major steps of forming a wafer-level heat spreader structure according to one embodiment of the present invention;

FIG. 1E is a cross-sectional view of a chip having a heat spreader structure according to one embodiment of the present invention mounted on a carrier by flip-chip bonding;

FIG. 1F is a cross-sectional view of a chip package structure formed after an underfill process is conducted according to one embodiment of the present invention; and

FIG. 1G is a cross-sectional view of a chip package structure with a heat sink provide thereon according to another embodiment of the present invention.

### DETAILED DESCRIPTION OF THE PREFERRED EMBODIMENT

Some embodiments of the present invention are set forth in detail below. However, the present invention may be embodied in many different forms in addition to the description set forth below. The scope of the present invention is, therefore, indicated by the appended claims and not limited by the specific embodiments illustrated and described. Furthermore, in this specification and the appended claims, the singular forms “a,” “an,” and “the” include plural reference unless the context clearly dictates otherwise. In addition, the components in the drawings are not necessarily to scale and certain features may be exaggerated or simplified in order to better illustrate and explain the present invention. Only the key points of the conventional art employed by the present invention are quoted to illustrate the present invention.

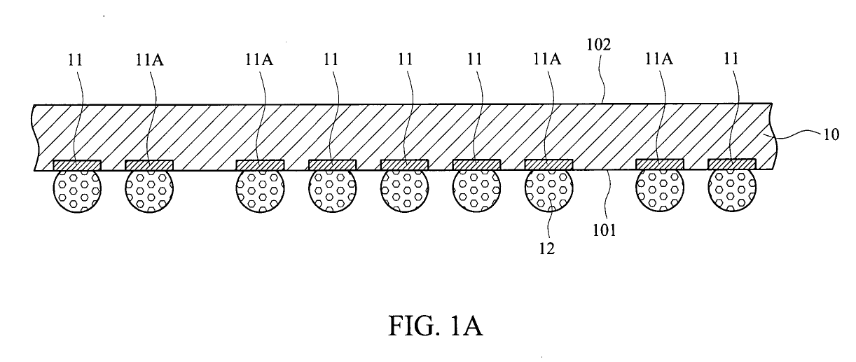

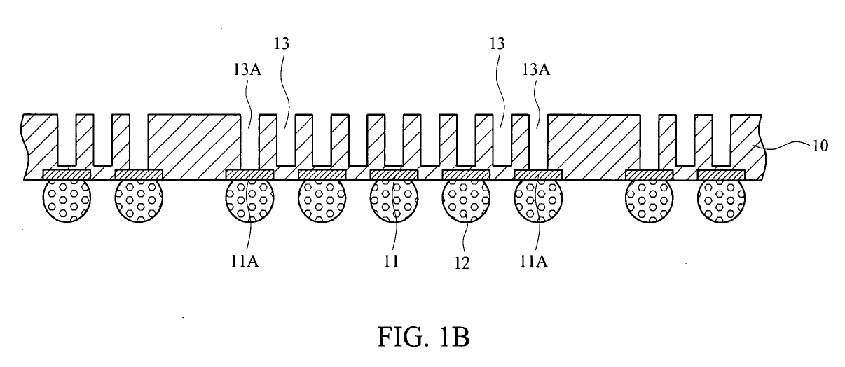

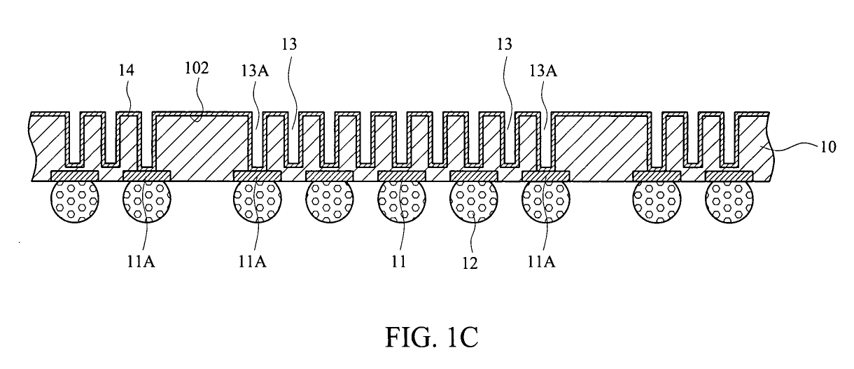

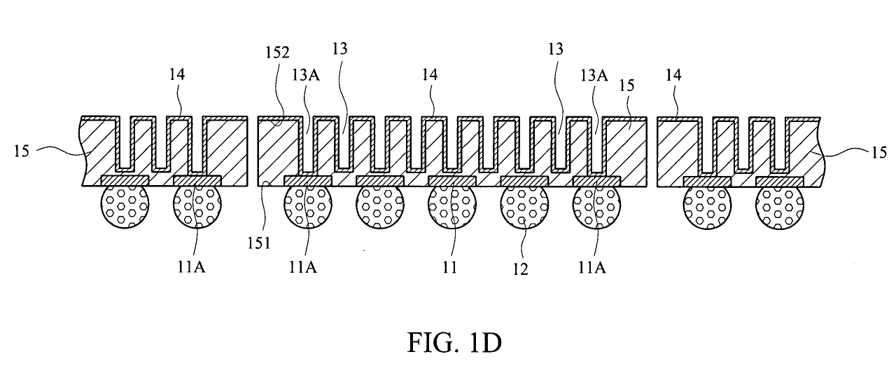

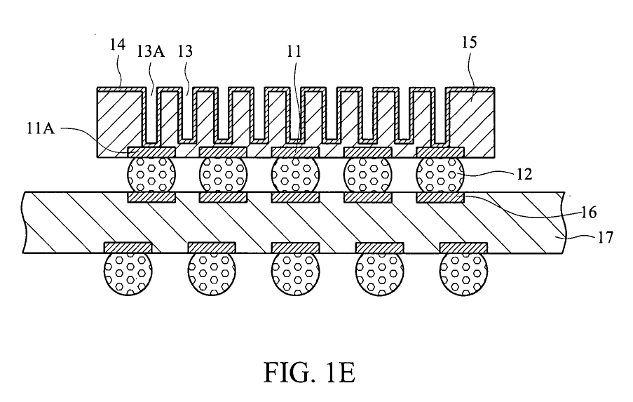

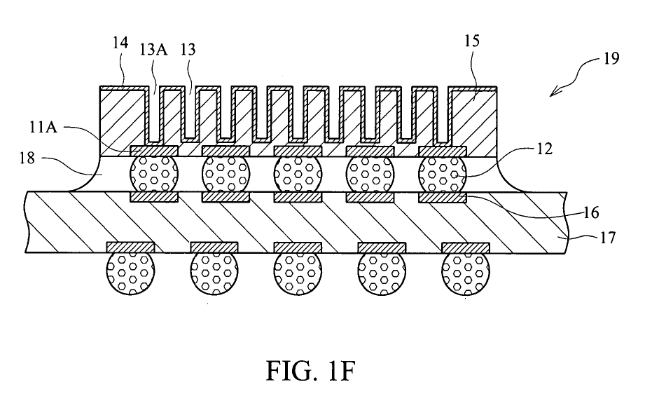

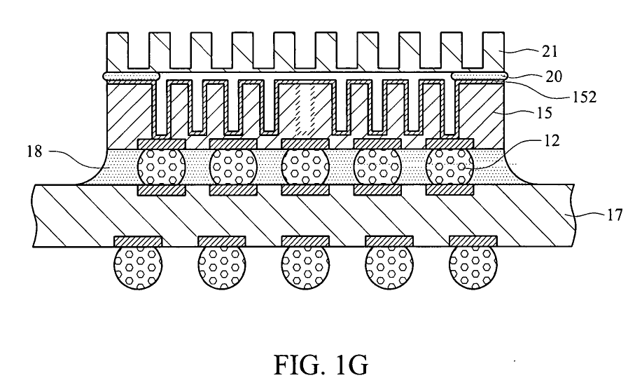

A method for forming a wafer-level heat spreader structure according to one embodiment of the present invention is disclosed below. FIG. 1A shows a wafer 10 having an active surface 101 and a backside surface 102. A plurality of bonding pads 11 and bumps 12 are formed on an active surface 101 wherein some of the bonding pads are used as ground pads 11A.

Referring to FIG. 1B, a plurality of via holes 13 are formed on the backside surface 102 of the wafer 10. In this embodiment, the via holes forming step is conducted by removing a portion of the wafer 10 via dry etching. Note that some via holes 13A are formed at locations corresponding to the ground pads 11A, and, during the etching process, the depth of the via holes 13A is controlled to be sufficient to exposes the surface of the ground pads 11A. Alternatively, in another embodiment of the present invention, the surface of the ground pads 11A may also be exposed by dry etching directly at the locations corresponding to the ground pads 11A.

Next, as shown in FIG. 1C, a heat conductive layer is formed over the backside surface 102 of the wafer 10, the via holes 13 and 13A, and the exposed bonding pad 11A thereby forming a heat spreader structure. In this embodiment, the heat conductive layer forming step is conducted by sputtering or electroplating a metal layer 14. The metal layer 14 directly contacts the exposed surface of the ground pads 11A thereby providing grounding for the area on the backside surface 102 of the wafer 10 which is covered by the metal layer 14.

After that, referring to FIG. 1D, the wafer is diced into a plurality of chips 15 by a sawing process. The backside surface 152 of each chip 15 is provided with the heat spreader structure constituted by the metal layer 14 and the via holes 13 and 13A, and the active surface 151 of each chip 15 is provided with bumps 12 capable of bonding with other chip or carrier (substrate). Therefore, as shown in FIG. 1E, the chip 15 may be stacked on a carrier 17 having contact pads 16 by flip chip bonding. After a reflowing process is performed, the bonding pads 11 on the chip 15 and the contact pads 16 on the carrier 17 are electrically interconnected by the bumps 12. Next, as shown in FIG. 1F, an underfill process is conducted to form underfill 18 between the chip 15 and the carrier 17, and the underfill 18 is cured to form a chip package structure 19. Alternatively, in another embodiment of the present invention, the underfill process can be skipped by adopting materials that combine the flux with the underfill materials such as non flow underfill (NFU) in the flip chip bonding step.

In still another embodiment of the present invention, depending on the actual heat dissipating requirement, the chip package structure 19 may be further provided with a heat sink 21 attached onto the backside surface 152 of the chip 15 by a conductive adhesive 20 (see FIG. 1G).

In this embodiment, the wafer-level heat spreader structure is formed by removing a portion of the backside of the wafer. However, the wafer-level heat spreader structure of the present invention is not limited to the via-hole structure, other structures such trench-like structure or even irregular cavity structure are still considered within the spirit and scope of the invention, with the proviso that the heat dissipating area on the backside surface of the wafer is increased to achieve a better heat dissipating performance.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A chip package structure, comprising:
a chip having an active surface and a backside surface, a plurality of bonding pads formed on the active surface, and a plurality of via holes formed on the backside surface, wherein at least one of the via holes exposes a portion of one of the bonding pads;
a heat conductive layer formed over the backside surface, the via holes, and the exposed bonding pad;
a carrier having a plurality of contact pads corresponding to the bonding pads; and
a plurality of bumps for electrically interconnecting the bonding pads and the contact pads.

2. The chip package structure according to claim 1, wherein the heat conductive layer is a metal layer.

3. The chip package structure according to claim 1, further comprising a heat sink attached on the heat conductive layer.

4. The chip package structure according to claim 3, further comprising a conductive adhesive provided between the heat sink and the heat conductive layer.

5. The chip package structure according to claim 1, further comprising an underfill formed between the chip and the carrier.
